(19) United States
(12) Patent Application Publication
(10) Pub. No.: US 2021/0141036 A1
(43) Pub. Date: May 13, 2021

(54) PORTABLE NMR PROBE AND NMR APPARATUS

(71) Applicants: Terence COSGROVE, Portishead, Somerset (GB); Stuart Walker PRESCOTT, Sydney, New South Wales (AU); Roger Bruce PETTMAN, Winter Park, FL (US)

(72) Inventors: Terence COSGROVE, Portishead, Somerset (GB); Stuart Walker PRESCOTT, Sydney, New South Wales (AU); Roger Bruce PETTMAN, Winter Park, FL (US)

(21) Appl. No.: 16/626,046

(22) PCT Filed: Jul. 6, 2018
(86) PCT No.: PCT/EP2018/068444

§ 371 Date: Dec. 23, 2019

Related U.S. Application Data
(60) Provisional application No. 62/604,424, filed on Jul. 6, 2017.

(51) Int. Cl. G01R 33/34; G01N 24/08; G01R 33/31; G01R 33/383; G01R 33/385

(52) U.S. Cl. CPC G01R 33/34007; G01N 24/08; G01R 33/3858; G01R 33/383; G01R 33/31

(57) ABSTRACT

A portable NMR probe for the analysis of dispersions, the portable NMR probe comprising: a base part; a detachable probe assembly detachably mounted on the base part and electrically connected to the base part, the detachable probe assembly comprising: a housing; and a radio-frequency coil assembly received in the housing, the radio-frequency coil assembly comprising an RF coil support that has a channel for receiving an NMR sample, and an RF coil wound around the RF coil support for transmitting radio-frequency pulses to the NMR sample and for detecting magnetic resonance responses from the NMR sample; and a field magnet arranged to generate a magnetic field in the detachable probe assembly.

### FIELD OF THE INVENTION

The present invention relates to a portable NMR probe, and to an NMR apparatus including a portable NMR probe. In particular, the present invention relates to a compact and portable NMR probe that can be used for analysis of colloidal and nanoparticle dispersions, polymer solutions/melts and the adsorption/displacement of adsorbed polymer and surfactants using pulsed NMR.

### BACKGROUND OF THE INVENTION

The vast majority of products manufactured for use in a wide variety of industrial applications, personal care, agrochemicals, pharmaceuticals and, increasingly, the growing field of nanomedicine involve, either in the final state or at some stage of their production, suspensions of particulate materials dispersed into a liquid often at high volume fraction. The vast array of, for example, cosmetic products demonstrate the importance of adequate dispersion. In decorative cosmetics, its importance to application properties and color is significant: the dispersion of colored organic/inorganic pigments and dyes affects brightness and gloss. In sunscreens, the quality of the dispersion not only affects the formulation aesthetics but also the performance (i.e. SPF factor). Increasingly, with Active Pharmaceutical Ingredients (API's) possessing poor aqueous solubility, optimal dispersion is necessary for maximizing bioavailability and uniformity of dose.

The state of dispersion of any solid material directly affects suspension properties. As particulate material is added to any liquid medium, its flow becomes increasingly non-Newtonian and, with high particle concentrations, can become thixotropic or rheopectic. These rheological characteristics determine suspension functionality such as film-forming, lubricity and efficacy.

The profound effect of the dispersion process on the economics and quality of the subsequent product has long been recognized.

As a practical example, cellulose nanomaterials (CNM) are an attractive alternative to other high-aspect-ratio nanoparticles, such as carbon nanotubes, silica nanowhiskers and clays, because of their renewable, sustainable origins and low toxicity. The ability to characterize key CNM properties quickly and reliably is critical to manufacture CNM—reproducibly with consistent particle geometry, surface properties and molecular-scale morphology—as an economically feasible product. However, quality control measurements need to be affordable, in-line, high-throughput and easy-to-use to facilitate manufacturing process monitoring. Unfortunately, many of the current techniques used to quantify these key properties are too time-consuming and expensive and may only apply to dilute and optically accessible dispersions.

In view of the above, it is important to be able to quickly and efficiently quantify key properties of dispersions and suspensions, in a wide range of different applications and environments.

Low-field pulsed NMR has been used previously to characterize a wide range of soft matter dispersions, and is used as a tool to measure for example the adsorption and displacement of complex mixtures of polymers and surfactants (for example see C. L. Cooper, T. Cosgrove, J. S. van Duijneveldt, M. Murray, and S. W. Prescott. The use of solvent relaxation NMR to study colloidal suspensions. Soft Matter, 9(30):7211-7228, 2013.).

It has been suggested that NMR measurements could possibly allow manufacturers to monitor the degree of chemical surface functionalization as well as the morphology (crystalline versus amorphous) of CNM. But this requires an NMR device that is suited to routine laboratory analysis.

Nuclear magnetic resonance (NMR) spectroscopy is one of the most powerful analytical tools used to probe details of molecular structure and dynamics. It usually requires very high magnetic fields and, hence, generally uses extremely large and powerful magnets. This means that NMR devices are typically large, bulky and expensive, which limits their application in many environments, for example in a manufacturing facility or for routine laboratory analysis.

The science behind NMR spectroscopy is well understood, so is not repeated here in detail. NMR is a well-known physical phenomenon in which nuclei in a magnetic field can absorb and re-emit electromagnetic radiation. This energy is at a specific resonance frequency that depends on the strength of the magnetic field and the magnetic properties of the isotope of the atom under study.

In more detail, all isotopes that contain an odd number of protons and/or neutrons have an intrinsic magnetic moment and angular momentum (they have a non-zero spin). Consider a nuclei that has a spin of one-half, for example ¹H. The nucleus has two possible spin states: m=1/2 (spin-up) and m=−1/2 (spin-down). In the absence of an applied magnetic field, these states have the same energy, and therefore the number of atoms in these two states will be equal at thermal equilibrium.

In the presence of an applied constant magnetic field B₀, the interaction between the nuclear magnetic moment and the applied magnetic field means that the energies of the two states are no longer equal, the energy difference being proportional to the magnitude of the applied magnetic field.

This energy difference results in a population bias towards the lower energy state (aligned with the magnetic field), and therefore a net magnetization M arises along the direction in which the magnetic field B₀ is applied.

When radio frequency electromagnetic radiation having a specific frequency (equaling the Larmor precession frequency) is applied to the sample, the net magnetization M is tipped out of alignment with the direction in which the magnetic field B₀ is applied, causing it to precess around the direction in which the magnetic field B₀ is applied (commonly designated as the z axis).

When the radio frequency electromagnetic radiation is subsequently stopped, a process of relaxation occurs, in which the net magnetization M returns to its original orientation in the z direction.

During relaxation, a signal can be detected by a coil wrapped around the sample. The signal is a small electrical current induced in the coil by the precession of the net magnetization M.

The time period over which relaxation occurs depends on the specific isotope and the environment (static and dynamic) in which the isotope is located as well as some instrumental specifics. The time period over which relaxation occurs can therefore provide detailed information about the sample being analyzed.

Typically, two different relaxation time periods are of interest: T₁ relaxation and T₂ relaxation. T₁ relaxation is the process by which the net magnetization M grows/returns to its initial maximum value parallel to the z axis (corresponding to thermal equilibrium). It is also known as spin-lattice relaxation. T₂ relaxation is the process by which the transverse components of the net magnetization (M_{xy}) decay. It is also known as spin-spin relaxation. These concepts are well understood in the field of NMR, so are not described here in any further detail.

In addition to the main applied constant magnetic field B₀, it is also common to apply a small gradient (pulsed and static) in the magnetic field across the sample, typically a linear variation in the magnetic field along one direction. This small gradient in the magnetic field is generated using further gradient coils positioned around the sample. The gradient in the magnetic field means that the specific resonant frequency of the radio-frequency electromagnetic radiation that needs to be applied varies along the direction in which the gradient in the magnetic field is applied, which means that spatial and diffusional information can also be encoded in the resulting NMR signals that are detected.

For NMR spectroscopy to be of practical use in the study of dispersions such as those discussed above, there is a need for a compact and portable NMR device that is suited to analysis of dispersions.

A recent patent U.S. Pat. No. 7,417,426 describes a compact and portable low-field NMR dispersion analyzer that is described as being specifically tailored to the measurement of dispersion physical properties.

Aspects of the NMR dispersion analyzer described in U.S. Pat. No. 7,417,426 are illustrated in FIGS. 10 and 11. In U.S. Pat. No. 7,417,426 an integrated portable NMR device is provided that includes an integrated probe module 1.

As shown in FIG. 10, the integrated probe module 1 includes plate-like circular permanent magnets 2 and 3 that are opposed to each other and held in position and alignment by a yoke 4. A space 5 is located between the opposed magnets 2 and 3.

As shown in FIG. 11, a single coil 6 is located in the space 5 for transmitting both radio-frequency pulses, detecting magnetic responses (signals from the sample) and delivering magnetic field gradient pulses. The coil in one example comprises 80 turns of insulated copper wire wound around a PTFE former that has an axial hole of suitable dimensions to allow the insertion of a standard NMR sample tube.

The present inventors have realized that significant improvements can be made to the NMR dispersion analyzer described in U.S. Pat. No. 7,417,426, and other NMR devices for use in investigating dispersions, so as to improve the applicability to adequately address many practical issues in dispersion technology.

### SUMMARY OF THE INVENTION

The present invention aims to provide a compact and portable NMR probe for use for analysis of dispersions.

According to a first aspect of the present invention there is provided a portable NMR probe for the analysis of dispersions, the probe comprising:

a base part;

a detachable probe assembly detachably mounted on the base part and electrically connected to the base part, the detachable probe assembly comprising:
a housing; and
a radio-frequency coil assembly received in the housing, the radio-frequency coil assembly comprising an RF coil support that has a channel for receiving an NMR sample, and an RF coil wound around the RF coil support for transmitting radio-frequency pulses to the sample and for detecting magnetic resonance responses from the sample; and

a field magnet arranged to generate a magnetic field in the detachable probe assembly.

In the first aspect of the present invention, the detachable probe assembly is detachable from the base part. This means that the detachable probe assembly can easily be removed from the base part, for example if a part of the detachable probe assembly is broken or if an NMR sample tube in the detachable probe assembly is broken, without having to take the entire portable NMR probe apart.

This also means that different detachable probe assemblies can be used with a single portable NMR probe, because different detachable probe assemblies can be interchanged rapidly. For example, different detachable probe assemblies in which the channels of the RF coil supports have different diameters can be used with a single portable NMR probe, meaning that NMR samples with different diameters can easily be investigated with a single portable NMR probe, especially for samples that are highly viscous or difficult to handle. This makes the portable NMR probe of the present invention very adaptable.

The first aspect of the present invention may optionally have any one, or, where they are compatible, any combination of the following optional features.

The term “base part” may not imply a particular orientation. For example, the “base part” does not necessarily need to be beneath the detachable probe assembly, and instead may be in any position or orientation.

Alternatively, “base part” may mean a part of the portable NMR probe that is at the bottom of the portable NMR probe in normal use of the portable NMR probed, for example when performing an NMR measurement.

The term “base part” may alternatively be replaced in the present application with the term “body part”, “box part” or “container part”.

The base part may be a box that contains an impedance matching circuit for matching the impedance of the portable NMR probe or of the detachable probe assembly to the impedance of a controlling device that supplies power and signals to the portable NMR probe, and/or a preamplifier.

Other components that may be provided in the base part, or otherwise provided on or connected to the portable NMR probe, may include a WiFi or Bluetooth transmitter for transmission of the NMR signal or physical measurements of the environment including temperature, humidity etc.

The term “detachable” may mean that the probe assembly can be removed from the base part without breaking or damaging any parts.

The term “detachable” may mean that the probe assembly can be pulled off of the base part merely by applying a force to the probe assembly.

Typically the probe assembly is electrically connected to the base part through the same parts by which it is detachably mounted on the base part.

Being electrically connected to the base part typically means that the probe assembly is electrically connected to a circuit inside the base part.

Portable may mean that the NMR probe can be picked up by a person.

For example, portable may mean that the NMR probe weighs less than 2.5 kg, for example 1.5 kg but as low as 600 g.

A total height of the detachable probe assembly above the base part when the detachable probe assembly is connected to the base part may be 88.5 mm. In another specific example the probe and magnet assembly (FIG. 4) may be miniaturized to 60×50×30 mm and weigh 600 g. Of course, the detachable probe assembly and magnet assembly may have a different size and/or weight to these values and could be substantially smaller.

The term “detecting” may mean “pick up”, “measure” or “record”, for example.

The housing of the detachable probe assembly may be a box, for example a metal box, for example aluminum.

The housing may have a rectangular shape.

The housing typically has a hollow interior for receiving the RF coil support.

The RF coil support may protrude from the housing via an opening in the housing, so that an NMR sample can be inserted into the channel of the RF coil support from outside of the housing.

Typically the opening is in an end face of the housing, for example a short end face of a rectangular housing.

The diameter of the opening in the housing may be larger than an outer diameter of the RF coil support where the RF coil support protrudes from the housing. A seal or support may therefore be provided to seal the gap between the outside of the RF coil support and the opening of the housing or to support the RF coil support within the housing. This may mean that different diameter RF coil supports can be used in the same shape and size of housing by varying a size of the seal or support. In particular, different diameter RF coil supports having different internal diameter channels can be used with the same shape and size housing. For example, an RF coil support having a channel with a diameter of 10 mm may be used in one example, which allows for measurements of viscous liquids, gels and semi-solid formulations.

The RF coil wound around the RF coil support is electrically connected to the base part, for receiving a radiofrequency signal.

The term “NMR sample” means a sample for which an NMR measurement is to be performed. Typically the NMR sample will be contained within a tube, for example a glass tube.

NMR may mean pulsed NMR.

The detachable probe assembly may be detachably mounted on the base part by one or more detachable connectors. Any suitable connectors may be used.

The detachable probe assembly may be detachably mounted on the base part by one or more mated male and female connectors.

The detachable probe assembly may have two protruding connectors on a surface thereof;

the base part may have two corresponding recessed connectors on a surface thereof; and

the two protruding connectors of the detachable probe assembly may be received in the corresponding recessed connectors of the base part, so as to detachably mount the detachable probe assembly on the base part and to electrically connect the detachable probe assembly to the base part.

This may be a convenient way to detachable mount the detachable probe assembly on the base part. For example, the detachable probe assembly may be detached from the base part by pulling the detachable probe assembly away from the base part.

The detachable probe assembly may be detachably mounted on the base part through two coaxial RF connectors.

The RF coil support may be a cylindrical tube having a portion with a reduced external diameter, and the RF coil may be wound around the portion with the reduced external diameter. This may make it easier to more accurately provide an RF coil with a predetermined number of windings.

The RF coil support may be a machined glass insert.

The reduced external diameter portion may form a recessed collar.

The detachable probe assembly may comprise a gradient coil for generating a magnetic field gradient across the sample.

The gradient coil may be a quadruple gradient coil.

The gradient coil may be a five-segment quadruple gradient coil for generating a magnetic field gradient across the sample. Such a gradient coil may provide larger and more uniform magnetic field gradients.

The gradient coil may be formed on a sheet and wrapped around the RF coil wound around the RF coil support. For example, the quadruple gradient coil may be printed on a plastic sheet, for example a Mylar sheet.

The detachable probe assembly may comprise three gradient coils for providing x-, y- and z-magnetic field gradients. This may enable three-dimensional imaging of an NMR sample, allowing measurement of flow measurements and anisotropic diffusion, for example.

The field magnet may have a channel there-through, the field magnet being arranged to generate a magnetic field in the channel; and

the detachable probe assembly may be inserted into the channel of the field magnet.

Thus, the detachable probe assembly can easily be removed from the field magnet by removing the detachable probe assembly from the channel.

The channel may be slot through the field magnet.

The channel may be enclosed on all sides by the field magnet so as to provide an interference shield that isolates the sample and protects and external devices.

The magnet typically comprises two pole pieces held by a yoke.

The field magnet may be a cylindrical magnet, i.e. the yoke is in the form of a cylinder housing two pole pieces or a cylindrical magnet of the Halbach type.

Typically the field magnet is a permanent magnet.

The detachable probe assembly may not be connected to the field magnet. This facilitates removal of the detachable probe assembly from the channel of the field magnet. Instead, the field magnet may be attached to the base part.

Different sizes and/or strengths of field magnet may be interchangeably connected to the portable NMR probe, allowing different magnetic field strengths to be applied to the detachable probe assembly. For example, magnets with field strength sufficient to result in a resonant frequency of between 0.5 MHz and 50 MHz may be interchangeably used with the portable NMR probe.

The NMR resonant frequency (ω) depends on the magnetic field (B) through the Larmor Equation, ω=γB, where γ is the gyromagnetic ratio. However, the field strength of the field magnet may vary with temperature of the field magnet (typically the magnetic field strength decreases monotonically as the temperature rises), such that the required resonant frequency also changes with temperature of the field magnet.

One option for dealing with this temperature variation of the resonant frequency is to perform a field-frequency lock procedure before an actual measurement is taken. For example, before each actual measurement a very rapid preliminary measurement may be taken to determine the required resonant frequency, for example by starting with a predetermined frequency and then stepping up or stepping down the frequency and measuring the difference frequency of the response from the excitation frequency. This may provide more reproducible data.

Therefore, the first aspect of the present invention may include performing one or more preliminary measurements before measuring an NMR sample to determine the resonant frequency.

Alternatively, the first aspect of the present invention may instead comprise actively controlling the temperature of the portable NMR probe to prevent any unwanted temperature variation, or to enable measurements to be made at some set or pre-determined temperature. Sample temperature control is important in many applications, especially pharmaceutical and biomedical studies.

Thus, the portable NMR probe may have temperature control means for controlling a temperature of the portable NMR probe.

Temperature control means may mean a temperature control device or temperature control part.

For example, the temperature control means may control a temperature of the field magnet, or a temperature of the air in the portable NMR probe.

Indeed, such temperature control may form a second aspect of the present invention. Therefore, according to a second aspect of the present invention there may be provided a portable NMR probe for the analysis of dispersions, the portable NMR probe comprising:

a field magnet arranged to generate a magnetic field in a measurement space;

an RF coil located in the measurement space for transmitting radio-frequency pulses to a sample in the measurement space, and for detecting magnetic resonance responses from the sample; and

temperature control means for controlling a temperature of the portable NMR probe.

The first or second aspects of the present invention may have any one, or, where they are compatible, any combination of the following optional features.

The temperature control means may comprise a Peltier device.

Alternatively, in another example the temperature control means may comprise a water cooled cooling device. For example, temperature controlled water may be recirculated through a heat exchanger in the portable NMR probe. One or more fans may be provided in the portable NMR probe to blow air over the heat exchanger. In other words, a heat exchanger may be provided in the portable NMR probe in which heat is exchanged between temperature controlled water circulating in one or more pipes and air blown by one or more fans. The heat exchanger may comprise a radiator.

Typically the temperature control means has a programmable temperature.

In conventional NMR devices, the generation of the radio-frequency signal for the coil and the detection of the magnetic resonance response are performed by a combination of analogue and digital circuits.

In a third aspect of the present invention, an NMR apparatus comprises the portable NMR probe according to the first or second aspect of the present invention (optionally with any of the optional features discussed above) and a Software Defined Radio device connected to the NMR probe and arranged to generate radio-frequency signals for the RF coil and to detect magnetic resonance responses detected by the RF coil.

Software Defined Radio is a radio communication system where components that have been traditionally implemented in hardware (e.g. mixers, filters, amplifiers, modulators/demodulators, detectors, etc.) are instead implemented by means of software. The Software Defined Radio implements Direct Digital Syntheses, in which analogue waveforms, such as a sine wave, are generated digitally by generating a time-varying signal in digital form and then performing a digital-to-analogue conversion.

Such an arrangement is significantly simpler, more efficient, and has a lower operating power demand than analogue circuit configurations.

Thus, in the third aspect of the present invention some, most or all of the radio-frequency generation and detection is done digitally, with no or minimal analogue steps. Furthermore, some, most or all required filtering and phase detection are done digitally.

A Software Defined Radio may provide better control of RF generation (using composite pulses), and RF detection and a very large pulse sequence library may be possible. Shaped pulses may also be provided.

A composite pulse is a number of contiguous, or near-contiguous, radio-frequency pulses with different phases.

A shaped pulse is a pulse in which the radio-frequency waveform has been controlled to have a specific shape.

In a fourth aspect of the present invention an NMR apparatus comprises:

a portable NMR probe for the analysis of dispersions, the portable NMR probe comprising:
a field magnet arranged to generate a magnetic field in a measurement space; and
an RF coil located in the measurement space for transmitting radio-frequency pulses to a sample in the measurement space, and for detecting magnetic resonance responses from the sample; and

a Software Defined Radio device connected to the NMR probe and arranged to generate radio-frequency signals for the RF coil and to detect magnetic resonance responses detected by the RF coil.

The third or fourth aspects of the present invention may have any one, or, where they are compatible, any combination of the following optional features.

The NMR apparatus may comprise a power amplifier connected between the Software Defined Radio device and the portable NMR probe for delivering the radio-frequency signals to the portable NMR probe.

The NMR apparatus may comprise a very low noise preamplifier connected between the portable NMR probe and the Software Defined Radio device for amplifying magnetic resonance responses detected by the portable NMR probe.

The NMR apparatus may comprise a computer connected to the Software Defined Radio device for controlling the Software Defined Radio device.

The Software Defined Radio device may comprise a console connected to the portable NMR probe, wherein the console comprises a reprogrammable memory for storing a program for implementing the Software Defined Radio device and a processor for executing the program.

In a fifth aspect of the present invention an NMR apparatus comprises a portable NMR probe according to the first or second aspect and separate electronics for powering and controlling the portable NMR probe.

Since the portable NMR probe is separate from the control electronics, the size of the NMR probe is reduced, and temperature variation of the NMR probe may be reduced, which may enable more accurate characterization of dispersion properties.

The control electronics may be provided in a console connected to the portable NMR device by a cable. A computer may then be connected to the console, for example by Ethernet, for controlling the console and portable NMR probe.

The portable NMR probe being separate from the control electronics or computer may also allow for remote operation of the NMR probe, for example in hazardous environments (e.g. radioactive or infections disease applications). For example, the NMR probe may be positioned up to 30 m from the control electronics (console) or computer. Of course, the maximum distance of the NMR probe from the control electronics is not limited to a specific value, and instead could be greater than 30 m. It may also make replacement of a broken NMR tube more straightforward.

In alternative embodiments, the portable NMR probe may connect wirelessly to control electronics (for example a controller or console) or a computer. In other words, there may not be any physical connection between the portable NMR probe and the computer.

In one embodiment, the control electronics for generating and detecting RF pulses and magnetic resonance responses is in a console electrically connected to the portable NMR probe by a cable, and the console is wireless communication with a separate processor, for example a computer.

In any of the third to fifth aspects the NMR apparatus may comprise a plurality of the portable NMR probes of the first or second aspect, wherein the plurality of the portable NMR probes are controlled by a single controller.

In any of the third to fifth aspects, the portable NMR probe may comprise a gradient coil for generating a magnetic field gradient across the sample; and

the NMR apparatus may be configured to control the gradient coil to apply a bipolar magnetic field gradient across the sample.

Using bipolar gradients may enable more precise measurements of diffusion (and other experiments).

In terms of its use as a means to study and improve colloid stability the probe and apparatus of the aspects of the present invention can be used to routinely make rapid measurements of polymer adsorption isotherms as well as depletion and the estimate of critical adsorption energies, competitive adsorption of surfactants and polymer, competitive adsorption with two polymers, competitive adsorption with two particles, accessible pore volume by solvent ingress, polymer solution viscosity, polymer solution/melts diffusion, solvent diffusion, 1D imaging for settling/solids concentration, and emulsion sizing.

The portable NMR probe may have more than one, for example two, independent frequency channels that can be used for measurements of more than one, for example two, different types of nuclei, for example Li and H, at the same time and also for decoupling.

As an alternative, the first aspect of the present invention may be expressed as follows:

An NMR probe for the analysis of dispersions, the NMR probe comprising:

a base part;

a detachable probe assembly detachably mounted on the base part and electrically connected to the base part, the detachable probe assembly comprising:
a housing; and
a radio-frequency coil assembly received in the housing, the radio-frequency coil assembly comprising an RF coil support that has a channel for receiving an NMR sample, and an RF coil wound around the RF coil support for transmitting radio-frequency pulses to the NMR sample and for detecting magnetic resonance responses from the NMR sample; and

a field magnet arranged to generate a magnetic field in the detachable probe assembly.

In other words, the “portable” term may be omitted. This term may also be omitted in the other aspects of the present invention.

The field magnet and detachable probe assembly can be further miniaturized to include 3 cm diameter pole pieces and a total magnet size of a 5 cm cube. The probe assembly can be miniaturized such that its outer dimensions are typically 5 cm×2 cm×0.5 cm using 2 mm diameter NMR tubes.

### BRIEF DESCRIPTION OF THE DRAWINGS

Embodiments of the present invention will now be discussed, by way of example only, with reference to the accompanying FIGS., in which:

FIG. 1 is a schematic view of a portable NMR probe according to embodiments of the present invention;

FIG. 2 is a photograph of a portable NMR probe according to embodiments of the present invention with the magnet removed;

FIG. 3 is a photograph of a portable NMR probe according to embodiments of the present invention;

FIG. 4 is a photograph of a portable NMR probe and control console according to embodiments of the present invention;

FIG. 5 is a schematic view of a radio-frequency coil assembly used in embodiments of the present invention;

FIG. 6 is a photograph of a detachable probe assembly used in embodiments of the present invention;

FIG. 7(a) is an illustration of a gradient coil used in embodiments of the present invention;

FIG. 7(b) is an illustration of coil arrangements in embodiments of the present invention;

FIG. 7(c) is a partial x-y projection of FIG. 7(a) for all 4 segments of the quadrupolar coil;

FIG. 8 shows experimental results of the T₂ relaxation time for a sample of water obtained with an embodiment of the present invention in a single scan—showing high stability, reproducibility and superior signal to noise;

FIG. 9 is an illustration of the control system for the NMR probe in embodiments of the present invention;

FIGS. 10 and 11 show a prior art NMR probe and control system.

### DETAILED DESCRIPTION OF THE PREFERRED EMBODIMENTS AND FURTHER OPTIONAL FEATURES OF THE INVENTION

As shown in FIGS. 1 to 4, a compact and portable NMR probe 7 in an embodiment of the present invention comprises a base part 8, a detachable probe assembly 9 detachably mounted on the base part 8 and a permanent field magnet 10 for generating a magnetic field in the detachable probe assembly 9.

The base part 8 contains an impedance matching circuit (not shown) for matching an impedance of the portable NMR probe 7 to an impedance of a control device or control circuit such as a computer, or intermediate control electronics such as a console. The base part 8 may also or alternatively contain other electronics, for example a preamplifier.

The base part 8 is typically an aluminum box.

The base part 8 has input and output connectors 11 for electrically connecting a control device or control circuit or intermediate electronics such as a console to the base part 8.

The detachable probe assembly 9 is detachably mounted on the base part 8 through two connectors 12. Typically the connectors 12 are RF coaxial connectors, for example two 50 ohm RF connectors.

In more detail, the detachable probe assembly 9 has two protruding connectors, and the base part 8 has two corresponding recessed connectors. The detachable probe assembly 9 is detachably mounted on the base part 8 by pushing the detachable probe assembly 9 towards the base part 8 so that the protruding connectors of the detachable probe assembly 9 are received in the corresponding recessed connectors of the base part 8. The detachable probe assembly 9 can be detached from the base part 8 by pulling the detachable probe assembly 9 away from the base part 8 to decouple the connectors 12.

The connectors 12 also form an electrical connection between the base part 8 (circuitry in the base part 8) and the detachable probe assembly 9. This is discussed in more detail below.

The permanent field magnet 10 is provided to generate a magnetic field across the detachable probe assembly 9.

As shown in FIG. 3, in one embodiment the permanent field magnet 10 is a cylindrical magnet 10 having a slot 13 formed there-through perpendicular to the axis of the cylindrical magnet 10. The slot 13 and the detachable probe assembly 9 have corresponding rectangular shapes, so that the detachable probe assembly 9 can be slotted inside the slot 13 as shown in FIG. 3.

The cylindrical magnet 10 comprises two magnetic pole pieces held in a cylindrical yoke.

The slot 13 is positioned in the space between the two magnetic pole pieces.

The magnetic pole pieces typically have parallel main surfaces and are typically axially aligned.

The cylindrical magnet 10 is bolted to the base part 8 but is not connected to the detachable probe assembly 9.

Therefore, the detachable probe assembly 9 can be detached from the portable NMR probe 7 by pulling the detachable probe assembly 9 away from the base part 8 through the slot 13. Thus, the detachable probe assembly 9 can be easily removed, for example for repair or for replacement with a different detachable probe assembly 9, without having to remove the cylindrical magnet 10 or otherwise disassemble the portable NMR probe 7.

Furthermore, the cylindrical magnet 10 can easily be removed from the portable NMR probe 7 by undoing the bolts. Therefore, different magnets having different field strengths which therefore generate different resonant frequencies can easily be interchanged in the present invention. For example, magnets providing field strengths that give resonant frequencies in the range of 10-50 MHz may be used.

The configuration of the detachable probe assembly 9 will now be discussed in more detail with reference to FIGS. 5 and 6.

As shown in FIGS. 5 and 6, the detachable probe assembly 9 comprises a housing 14 which has the form of a box. In FIG. 6 the top of the housing 14 (which is visible in FIG. 2) has been removed so that the inside of the housing 14 can be seen.

The housing is typically made of aluminum.

the housing 14 has a rectangular shape, and is hollow.

Inside the housing 14 is an RF coil support 15. Part of the RF coil support 15 protrudes from the housing through an opening at the top of the housing (through a side of the housing, the side being the short side of the rectangle). The RF coil support insert 15 is typically made of machined glass. As shown in FIG. 5, the RF coil support may have a length of approximately 11 mm and a maximum outer diameter of approximately 7 mm.

The RF coil support 15 is cylindrical and has an axial channel along its entire length, so that the RF coil support 15 has the form of a cylindrical tube. In one example the diameter of the axial channel may be approximately 5.05 mm. The axial channel is for receiving an NMR sample in an appropriate NMR sample holder (for example a glass tube).

Since the RF coil support 15 protrudes outside of the housing 14, an NMR sample can be inserted into the channel of the RF coil support 15 from outside of the housing 14.

The RF coil support 15 has a recessed collar portion 16, over which the outer diameter of the RF coil support is uniformly reduced.

As shown in FIG. 6, an RF coil 17 is wound around the recessed collar portion 16 of the RF coil support 15, so as to surround part of the channel in the RF coil support 15. The RF coil 17 is therefore appropriately positioned to apply a radio-frequency signal to a sample in the channel of the RF coil support 15 and to detect a magnetic resonance response from the sample.

The RF coil 17 is electrically connected to electrical connectors of the detachable probe assembly 9, so that an electrical connection can be made to the RF coil 17 to supply appropriate radio-frequency signals and to receive the detected magnetic resonance responses.

As is apparent from FIG. 6, different sizes of RF coil support 15 can be housed in the same size and shape of housing 14 by varying the size of the opening of the housing 14, or by providing different sizes of sealing members such as O-rings or rubber seals or supports for supporting the RF coil support 15 in the opening of the housing 14. Thus, different detachable probe assemblies 9 having the same size and shape housing 14 but having RF coil supports 15 with different diameter channels can be provided, and the different detachable probe assemblies 9 can easily be switched as needed to match a sample container size by quickly detaching a detachable probe assembly 9 and attaching a different detachable probe assembly 9.

As shown in FIG. 4, in embodiments the portable NMR probe 7 may have an outer housing to cover the components of the portable NMR probe 7. In addition, separate electronics provided in a separate console 18 can be connected to the portable NMR probe by a cable of any length, for example 10 m. These separate electronics are discussed below.

The NMR probe assembly 7 when fully assembled may have a circular base and a domed top.

As shown in FIGS. 7(a), 7(b) and 7(c), in embodiments of the present invention a 5 segment quadruple gradient coil 19 may be provided. As shown in FIG. 7(a), the 5 segment quadruple gradient coil comprises 5 different coils printed onto a sheet, for example a Mylar sheet, to form a flexible printed circuit board. The pattern is repeated for each of the four poles of the quadruple. The sheet is then wrapped around the RF coil support 15 over the RF coil 17 to provide a gradient coil 19 around the channel in the RF coil support 15. Electrical connections are then formed between the gradient coil 19 and the base part 8 through a plug and socket, to provide appropriate gradient coil signals to the gradient coil 19 and to also be detachable.

Each of the 5 segments of the gradient coil 19 may have a different thickness. For example, the middle of the 5 segments may have the greatest thickness.

The arrangement of the gradient coil 19 around the RF coil support 15 is illustrated schematically in FIG. 7(b). However, only the vertical section of the segment of the gradient coil 19 having the greatest thickness is shown in FIG. 7(b) for clarity, and is labeled as “20”.

FIG. 7(c) schematically shows an x-y projection of the 5 segments of the gradient coil 19. The size of the dot corresponds to the thickness of the segment.

The configuration of the portable NMR probe 7 in the present invention can substantially improve the signal-to-noise ratio relative to previous devices. FIG. 8 is a graph showing results of measurements performed with the portable NMR probe 7 of the present invention to measure the T2 relaxation time for a sample of water. The graph shows that the single exponential line perfectly fits the raw data, which allows for a very precise determination of the relaxation time. In the illustrated example, the measured value for water was 2443 ms with an error of only 0.43 ms. The data shown is for a single scan.

FIG. 9 illustrates how the portable NMR probe is controlled in some embodiments of the present invention.

As shown in FIG. 9, embodiments of the present invention include a Software Defined Radio Device for controlling the portable NMR probe 7. Typically the Software Defined Radio Device will be provided in the console 18 shown in FIG. 4, which is connected to the portable NMR probe 7 by a cable.

Software Defined Radio is a radio communication system where components that have been traditionally implemented in hardware (e.g. mixers, filters, amplifiers, modulators/demodulators, detectors, etc.) are instead implemented by means of software. The Software Defined Radio implements Direct Digital Syntheses, in which analogue waveforms, such as a sine wave, are generated digitally by generating a time-varying signal in digital form and then performing a digital-t-analogue conversion.

Such an arrangement is significantly simpler, more efficient, and has a lower operating power demand than analogue circuit configurations.

The Software Defined Radio may be implemented using a processor and memory in the console 18. For example, programming code stored in the memory may be executed by the processor to produce desired radio-frequency excitations required for the RF coil 17 and to detect the detected magnetic resonance response picked up by the RF coil 17.

A power amplifier PA is connected between the Software Defined Radio device and the portable NMR probe for delivering the radio-frequency signals to the portable NMR probe.

A preamplifier is connected between the portable NMR probe and the Software Defined Radio device for amplifying magnetic resonance responses detected by the portable NMR probe.

Alternatively, one or both of the power amplifier or preamplifier may be located in the base part 8 of the portable NMR probe 7.

A computer is connected to the Software Defined Radio device for controlling the Software Defined Radio device.

The computer is connected to the Software Defined Radio device via a fast Ethernet connection, making remote control possible and providing fast data connections. Because of the real-time fast Ethernet connection, data length is virtually unlimited.

Although not illustrated, embodiments of the present invention may comprise temperature control means for controlling a temperature of the portable NMR probe. For example, the temperature control means may be a Peltier device.

The temperature control means may control a temperature of the field magnet 10, or of the air in the portable NMR probe 7.

The portable NMR probe may have more than one, for example two, independent, frequency channels that can be used for measurements of more than one, for example two, different types of nuclei, for example Li and H, at the same time and also for decoupling.

In embodiments of the present invention the pulse length resolution may be 8 ns. This proves both a more accurate setting of instrument parameters as well as much improved accuracy in measurement of relaxation times, for example when compared the device disclosed in U.S. Pat. No. 7,417,426.

The RF coil support 15 may have a diameter between 2 to 12 mm, for example. Of course, in other embodiments the RF coil support may have a diameter different to this. Different detachable probe assemblies 9 may be provided having RF coil supports 15 with different diameter channels, so that different size samples can easily be measured using the same device.

The transmitter may be optimized to give a pulse length of less than 3 μs, for example.

The apparatus of the present invention may incorporate two 14 bit, 8 ns analogue-to-digital converters to give superior time resolution; RF pulses up to 1 ms at 8 ns resolution; any phase shift from 0-360 degrees; and dual frequency generation.

In one specific example the portable NMR probe 7 of the present invention may have dimensions of 220 mm diameter and 200 mm height, and a weight of 1.5 kg.

In another specific example the probe (FIG. 4) may be miniaturized to 60×50×30 mm and weigh 600 g, for example.

In one specific example, the console of the present invention may have dimensions of 125 mm height, 360 mm length and 250 mm width, and a weight of 6.3 kg.

In embodiments of the present invention, the field magnet comprises magnetic pole pieces held in place by a cylindrical yoke. The design in U.S. Pat. No. 7,417,426 provides only limited mechanical alignment of the magnet pole pieces, providing some coarse shimming. This directly impacts field homogeneity—a critical parameter as it directly influences sensitivity and signal-to-noise ratio. Further, replacement of the magnet pole pieces is not possible.

The simpler design in embodiments of the present invention (see FIGS. 7(a)-7(c)) is much easier to set up, requires no alignment of the magnetic pole pieces which have an optimized shim design, gives superior field homogeneity over the sample volume and signal-to noise ratio is substantially improved. In addition, the more accessible space makes it possible to generate multiple field gradients. Further, magnets of different designs can be easily exchanged to provide different field strengths (10-50 MHz) and sample volumes.

The present invention may alternatively be described as set out below.

The present invention seeks substantial improvements over the disclosure of U.S. Pat. No. 7,417,426.

1. The NMR device of U.S. Pat. No. 7,417,426 consists of a single small footprint enclosure integrated within which are both the magnet assembly and the associated electronics. This necessitates temperature control of the enclosure because of the heat generated by the power supply, etc. However, U.S. Pat. No. 7,417,426 makes no mention of this. The typical temperature rise depends upon the ambient temperature of the environment where the device resides but can easily be more than 5° C. above ambient. Characterization of dispersion properties need to be made at constant temperature. Modification of the enclosure to allow for temperature control is not a trivial exercise. This limits the utility to controlled environment laboratories and precludes use in plants. Importantly, any change in temperature results in a shift in the resonant frequency which must be constantly manually re-set.

Embodiments of the present invention separate the magnet assembly from the electronics.

The small probe head/pod assembly (see FIG. 1) has direct, programmable temperature control by means of a small Peltier device. The resonant frequency is continuously monitored and, if necessary, automatically re-set. High temperatures up to 80° C. can be achieved. This is simply not feasible with the design of the device of U.S. Pat. No. 7,417,426.

The separate pod assembly also allows for remote operation, for example in hazardous environments (e.g. radioactive and infectious disease applications).

It also makes replacement of a broken NMR tube straightforward. In the U.S. patent device, this necessitates removal of the yoke/magnet assembly from inside the enclosure.

Conversion of the probe head to a flow-through version for use in manufacturing process operation is simple. This is a very important practical advantage. For example, it makes sampling of heterogeneous materials much more reproducible. No mention of such a flow-option is made in U.S. Pat. No. 7,417,426 but it would be very difficult to modify that device.

Exchanging probe heads or using multiple heads is now enabled. This significantly extends the utility of the device for particle characterization. It also allows for different probe nuclei to be used.

Multiple heads can be driven by one controller.

2. The probe assembly in embodiments of the present invention (see FIG. 2) provides much more flexibility in terms of the sample volume that can be measured, as well as measurement sensitivity. The NMR device of U.S. Pat. No. 7,417,426 is limited to a single fixed diameter NMR tube (4 mm ID) that is custom made.

A variety of different diameter standard supply NMR tubes can be used in embodiments of the present invention. For example, a larger 10 mm diameter tube allows for measurement of viscous liquids, gels and semi-solid formulations.

Embodiments of the present invention employ a 5 segment quadrapolar coil for larger and more uniform field gradients. The US Pat. No. 7,417,426 device uses only a single segment coil.

Embodiments of the present invention utilize three gradient coils for 3D imaging, flow measurements and anisotropic diffusion. This is not possible with the U.S. Pat. No. 7,417,426 design and functionality is limited by the electronic design.

Embodiments of the present invention also use bipolar gradients and can employ unlimited pulse sequences and digital control of peripherals—to provide more precise measurements of diffusion (and all other experiments)—in conjunction with phase cycling and coherent noise reduction. None of this is possible with the device in U.S. Pat. No. 7,417,426.

3. The Yoke holds the magnets in place. The design in U.S. Pat. No. 7,417,426 provides only limited mechanical alignment of the magnet pole pieces, no shimming is possible. This directly impacts field homogeneity—a critical parameter as it directly influences sensitivity and signal-to-noise ratio. Further, replacement of the magnet pole pieces is not possible.

The simpler design in embodiments of the present invention (see FIGS. 7(a)-7(c)) is much easier to set up. It provides maximum mechanical alignment of the magnetic pole pieces and the optimized shim design gives superior field homogeneity over a larger volume.

In addition, the extra space makes it possible to generate multiple field gradients

Signal-to noise ratio is substantially improved.

Further, magnets of different designs can be easily exchanged to provide different field strengths (10-50 MHz).

4. The electronic layout in the U.S. Pat. No. 7,417,426 device is based on that employed in conventional, traditional NMR devices.

In contrast (see FIG. 9), embodiments of the present invention have a much simpler and straightforward electronic layout based on the new technique of Direct Digital Synthesis (DDS) which incorporates a software defined radio (SDR) device. This design is much more efficient with a lower operating power demand.

Here all RF generation and detection is done digitally; there are no analogue steps in detecting the NMR signal.

All filtering and phase detection is done digitally.

Embodiments of the present invention incorporate two 14 bit, 8 ns analogue-digital-converters (ADCs) giving superior time resolution; RF pulses up to 1 ms at 8 ns resolution; any phase shift from 0-360 degrees; dual frequency generation.

The SDR device provides better control of RF generation (using composite pulses).

A very large pulse sequence library is possible.

Some additional advantage of embodiments of the present invention are set out below:

The design of embodiments of the present invention provides many measurement advantages that cannot be performed using the U.S. Pat. No. 7,417,426 device.

1. There is a significant enhancement in the speed of data processing. This reduces the measurement time permitting the study of kinetic processes, settling, sedimentation, etc.

2. The vast improvement in measurement sensitivity allows study of highly paramagnetic materials and a broader range of dispersion concentrations and composition.

3. Robust self-diffusion measurement from water to viscous liquids 10⁻⁹ to 10⁻¹² m²s⁻¹.

4. Droplet sizing analysis of O/W and W/O emulsions; nano- and micro-emulsions.

5. Polymer characterization in solution and also in melts.

6. 1D, 2D and 3D imaging.

7. Measurement of solid materials.

8. Direct measurement of the solid/liquid ratio. This is an important and useful parameter and there is no other direct measurement available.

1. A portable NMR probe for the analysis of dispersions, the portable NMR probe comprising:
a base part;
a detachable probe assembly detachably mounted on the base part and electrically connected to the base part, the detachable probe assembly comprising:
a housing; and
a radio-frequency coil assembly received in the housing, the radio-frequency coil assembly comprising an RF coil support that has a channel for receiving an NMR sample, and an RF coil wound around the RF coil support for transmitting radio-frequency pulses to the NMR sample and for detecting magnetic resonance responses from the NMR sample; and
a field magnet arranged to generate a magnetic field in the detachable probe assembly.

2. The portable NMR probe according to claim 1, wherein the detachable probe assembly is detachably mounted on the base part by one or more detachable connectors.

3. The portable NMR probe according to claim 1, wherein the detachable probe assembly is detachably mounted on the base part by one or more mated male and female connectors.

4. The portable NMR probe according to claim 1, wherein:
the detachable probe assembly has two protruding connectors on a surface thereof;
the base part has two corresponding recessed connectors on a surface thereof; and
the two protruding connectors of the detachable probe assembly are received in the corresponding recessed connectors of the base part, so as to detachably mount the detachable probe assembly on the base part and to electrically connect the detachable probe assembly to the base part.

5. The portable NMR probe according to claim 1, wherein the detachable probe assembly is detachably mounted on the base part through two coaxial RF connectors.

6. The portable NMR probe according to claim 1, wherein the RF coil support is a cylindrical tube having a portion with a reduced external diameter, and wherein the RF coil is wound around the portion with the reduced external diameter.

7. The portable NMR probe according to claim 1, wherein the detachable probe assembly comprises a gradient coil for generating a magnetic field gradient across the sample.

8. The portable NMR probe according to claim 7, wherein the gradient coil is a quadruple gradient coil.

9. The portable NMR probe according to claim 7, wherein the gradient coil is a five-segment quadruple gradient coil.

10. The portable NMR probe according to claim 7, wherein the gradient coil is formed on a sheet and wrapped around the RF coil wound around the RF coil support.

11. The portable NMR probe according to claim 1, wherein the detachable probe assembly comprises three gradient coils for providing x-, y- and z-magnetic field gradients.

12. The portable NMR probe according to claim 1, wherein:
the field magnet has a channel there-through, the field magnet being arranged to generate a magnetic field in the channel; and
the detachable probe assembly is inserted into the channel of the field magnet.

13. The portable NMR probe according to claim 1, wherein the field magnet is a cylindrical magnet assembly.

14. The portable NMR probe according to claim 1, wherein the detachable probe assembly is not connected to the field magnet.

15. The portable NMR probe according to claim 1, wherein the portable NMR probe has temperature control means for controlling a temperature of the portable NMR probe.

16. A portable NMR probe for the analysis of dispersions, the portable NMR probe comprising:
a field magnet arranged to generate a magnetic field in a measurement space;
an RF coil located in the measurement space for transmitting radio-frequency pulses to a sample in the measurement space, and for detecting magnetic resonance responses from the sample; and
temperature control means for controlling a temperature of the portable NMR probe.

17. The portable NMR probe according to claim 15, wherein the temperature control means comprises a Peltier device.

18. The portable NMR probe according to claim 15, wherein the temperature control means has a programmable temperature.

19. An NMR apparatus comprising the portable NMR probe according to claim 1 and a Software Defined Radio device connected to the NMR probe and arranged to generate radio-frequency signals for the RF coil and to detect magnetic resonance responses detected by the RF coil.

20. An NMR apparatus comprising:
a portable NMR probe for the analysis of dispersions, the portable NMR probe comprising:
a field magnet arranged to generate a magnetic field in a measurement space; and
an RF coil located in the measurement space for transmitting radio-frequency pulses to a sample in the measurement space, and for detecting magnetic resonance responses from the sample; and
a Software Defined Radio device connected to the NMR probe and arranged to generate radio-frequency signals for the RF coil and to detect magnetic resonance responses detected by the RF coil.

21. The NMR apparatus according to claim 19, wherein the apparatus comprises a power amplifier connected between the Software Defined Radio device and the portable NMR probe for delivering the radio-frequency signals to the portable NMR probe.

22. The NMR apparatus according to claim 10, wherein the apparatus comprises a preamplifier connected between the portable NMR probe and the Software Defined Radio device for amplifying magnetic resonance responses detected by the portable NMR probe.

23. The NMR apparatus according to claim 19, further comprising a computer connected to the Software Defined Radio device for controlling the Software Defined Radio device.

24. An NMR apparatus comprising the portable NMR probe according to claim 1 and separate electronics for powering and controlling the portable NMR probe.

25. The NMR apparatus according to claim 19, wherein the NMR apparatus comprises a plurality of the portable NMR probes of any one of claims 1 to 18, wherein the plurality of the portable NMR probes are controlled by a single controller.

26. The NMR apparatus according to claim 19, wherein:
the portable NMR probe comprises a gradient coil for generating a magnetic field gradient across the sample; and
the NMR apparatus is configured to control the gradient coil to apply a bipolar magnetic field gradient across the sample.

27. The NMR apparatus according to claim 19, wherein:
the NMR apparatus is configured to monitor the frequency of radio-frequency pulses that need to be applied to a sample to generate a magnetic resonance response from the sample.

28. The NMR apparatus according to claim 27, wherein the monitoring is continuous.

29. The NMR apparatus according to claim 27, wherein the NMR apparatus is configured to automatically re-set the frequency of radio-frequency pulses applied to the sample based on the results of the monitoring.
